(19) United States
(12) Patent Application Publication
(10) Pub. No.: US 2003/0016742 A1
(43) Pub. Date: Jan. 23, 2003

(54) Digital filter

(76) Inventor: Yoshimitsu Asahina, Tokyo (JP)

Correspondence Address: SAMUEL BORODACH, Fish & Richardson P.C., Suite 2800, 45 Rockefeller Plaza, New York, NY, 10111, US

(21) Appl. No.: 10/194,341

(22) Filed: Jul. 12, 2002

(30) Foreign Application Priority Data
Jul. 17, 2001 (JP) P.2001-216703

(51) Int. Cl. H03H 7/40

(52) U.S. Cl. 375/229

(57) ABSTRACT

A digital filter 10 comprising a backward filter 12 for inputting a discrete signal S1 and a filter coefficient S14 and outputting a post-backward-filter signal S12 and a forward filter 13 for inputting the post-backward-filter signal S12 and the filter coefficient S14 and outputting a post-forward-filter signal S13.

### BACKGROUND OF THE INVENTION

The present invention relates to a digital filter, and in particular to a digital filter that has a linear phase characteristic and minimizes the transient response time of a discrete signal with an amplitude steeply varying in a short period thereby limiting a frequency band.

Related art digital filters will be described referring to the drawings.

FIG. 2 is a block diagram of a related art digital filter.

As shown in FIG. 2, a digital filter 20 comprises an FIR (Finite-Impulse-Response) filter 21 and a filter coefficient table 22 and has a linear phase characteristic.

The FIR filter 21 acquires a discrete signal S1 by way of sampling and performs convolutional integration of the discrete signal S1 based on an FIR filter coefficient S22 and outputs a post-FIR-filter signal S21.

The filter coefficient table 22 tabulates and retains the FIR filter coefficient S22 necessary for FIR filtering.

The size of the filter coefficient table 22, that is, the number of taps of an FIR filter is arbitrary. An increase/decrease in the number of taps is equivalent to an increase/decrease in the delay and the size of sum of product (SOP) circuit internal to the FIR filter 21.

In general, to obtain favorable filter characteristics, for example to provide a steep cut-off characteristic and greater attenuation of a cut-off frequency band, the number of taps increases considerably.

In case a discrete signal whose amplitude steeply varies in a short period is input to a related art digital filter, the amplitude varies steeply then the filter is influenced by the state before variation in amplitude for the duration of half the number of taps of the filter due to the characteristics of an FIR filter, thus causing the transient response.

As the number of taps is increased, duration of the transient response increases. As the number of taps is decreased, duration of the transient response decreases with degraded filter characteristics.

An IIR (Infinite-Impulse-Response) filter that has been known same as the FIR filter obtains a steep attenuation characteristic with a small number of taps. However, the IIR filter has a nonlinear phase characteristic.

The object of the invention is to provide a novel digital filter with excellent transient response and having a linear phase characteristic.

### SUMMARY OF THE INVENTION

In order to solve the aforementioned problem, a novel digital filter with excellent transient response and having a linear phase characteristic is obtained by composing a digital filter with a backward filter 12 for inputting a discrete signal S1 and a filter coefficient S14 and outputting a post-backward-filter signal S12 and a forward filter 13 for inputting the post-backward-filter signal S12 and the filter coefficient S14 and outputting a post-forward-filter signal S13 (first aspect).

By using IIR digital filters as a backward filter and a forward filter, it is possible to obtain a steep attenuation characteristic of a digital filter according to the first aspect with a small number of taps. This solves the problem of that the IIR filter has a nonlinear phase characteristic (second aspect).

By providing delay means (discrete signal shift -section) for delaying an input discrete signal in the earlier stage of the backward filter, it is possible to suppress divergence of the IIR digital filter as well as reduce the duration of transient response (third aspect).

By sharing the same filter coefficient between the backward filter and the forward filter, it is possible to reduce the capacity of a table storing the filter coefficient as well as obtain a linear phase characteristic (fourth aspect).

By arranging so that the input discrete signal will pass through the backward filter and the forward filter a plurality of times, it is possible to provide a more favorable frequency band limitation (fifth aspect).

By arranging so that the input discrete signal will pass through the backward filter and the forward filter a plurality of times and that the number of times is identical between both filters, it is possible to obtain a linear phase characteristic (sixth aspect).

### BRIEF DESCRIPTION OF THE DRAWINGS

FIG. 1 is a block diagram of a digital filter according to the invention;

FIG. 2 is a block diagram of a related art digital filter;

FIG. 3 shows an example of a discrete signal input to a digital filter;

FIG. 4 shows a post-FIR-filter signal obtained in case the discrete signal in FIG. 3 is input to a related art digital filter;

FIG. 5 shows a post-shift signal obtained in case the discrete signal in FIG. 3 Is input to a digital filter according to the invention;

FIG. 6 shows a post-backward-filter signal obtained in case the discrete signal in FIG. 3 is input to a digital filter according to the invention;

FIG. 7 shows a post-forward-filter signal obtained in case the discrete signal in FIG. 3 is input to a digital filter according to the invention;

FIG. 8 shows another example of a discrete signal input to a digital filter according to the invention.

### DETAILED DESCRIPTION OF THE PREFERRED EMBODIMENTS

An embodiment of the invention will be detailed referring to the drawings.

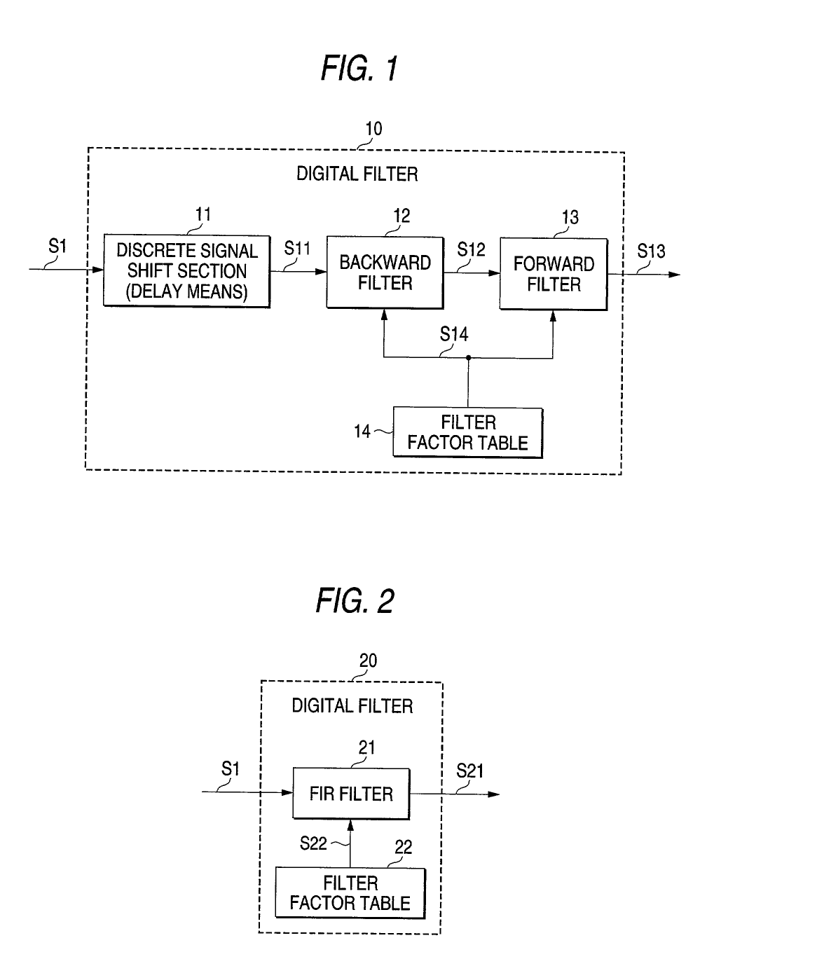

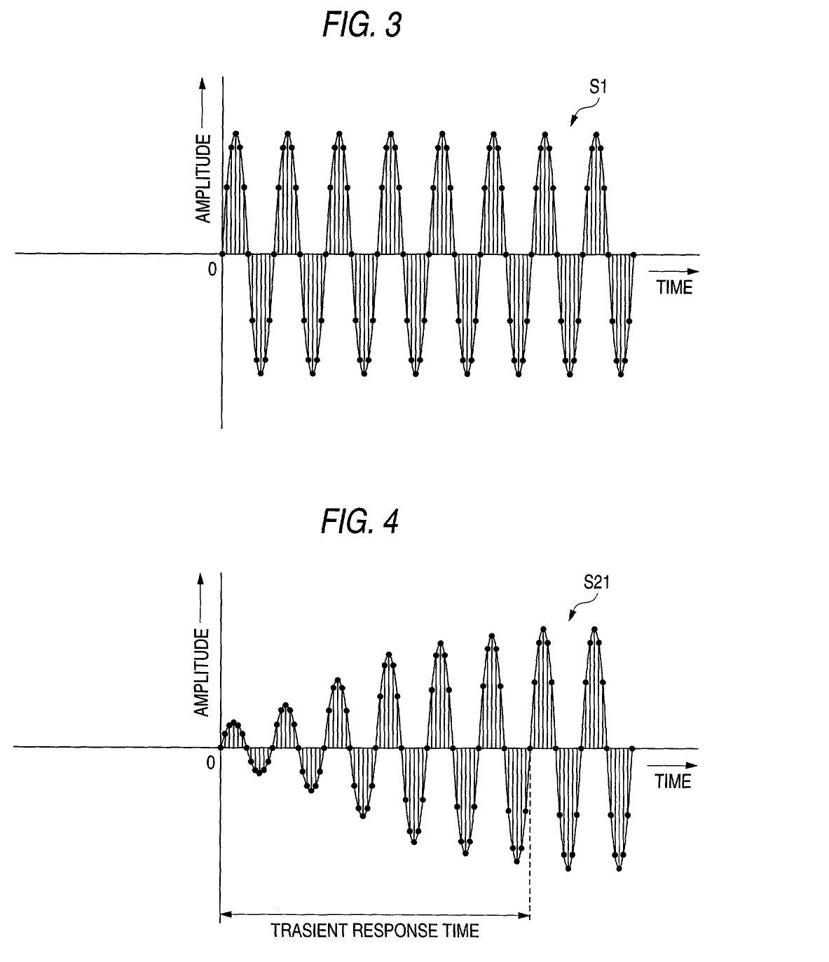

FIG. 1 is a block diagram showing the configuration of a digital filter.

Referring to FIG. 1, a digital filter 10 comprises a discrete signal shift section 11 for inputting a discrete signal S1 and outputting a post-shift signal S11, a backward filter 12 for inputting the post-shift signal S11 and a filter coefficient S14 and outputting a post-backward-filter signal S12, and a forward filter 13 for inputting the post-backward-filter signal S12 and the filter coefficient S14 and outputting a post-forward-filter signal S13. IIR digital filters are preferably used as the backward filter 12 and the forward filter 13.

It is generally known that a steep attenuation characteristic of an IIR filter is obtained with a small number of taps. However, an IIR filter has a nonlinear phase characteristic; it is not favorable to simply use an IIR filter because the output phase will vary.

A digital filter according to the invention has a master-slave configuration comprising a backward IIR filter for inputting a discrete signal and a filter coefficient and a forward IIR filter for inputting a post-backward-filter IIR signal and the filter coefficient. With this configuration, by filtering a discrete signal forward and backward or backward and forward, a linear phase characteristic is obtained, although a nonlinear phase characteristic is obtained in case filtering is made forward (or backward) a single time, as shown in FIG. 1.

A digital filter 10 shown in FIG. 1 uses IIR filters as the backward filter 12 and the forward filter 13 in order to obtain a steep attenuation characteristic with a small number of taps. The same filter coefficient 14 is shared between the backward filter 12 and the forward filter 13.

By performing filtering through the backward filter 12 and the forward filter 13 a plurality of times respectively, a more favorable frequency band limitation is obtained than filtering only once.

Note that the number of times filtering is made through the backward filter 12 must be identical with the number of times filtering is made through the forward filter 13 in order to obtain a linear phase characteristic.

The foregoing example assumes that a filter coefficient and a number of filtering repetitions are the same between the backward filter and the forward filter, it is to obtain a linear phase characteristic. In case an arbitrary nonlinear phase characteristic, different filter coefficients and difference number of filtering repetitions maybe used between the backward filter and the forward filter.

In the configuration of FIG. 1, a discrete signal shift section (delay means) is provided in the earlier stage of the backward filter 12, so that the digital filter 10 is capable to minimize the transient response time of the discrete signal S1 whose amplitude steeply varies in a short period thus limiting the frequency band.

Next, the operation of the digital filter 10 of the invention to minimize the transient response time of the discrete signal S1 whose amplitude steeply varies in a short period thus limiting the frequency band will be described in comparison with a related art digital filter shown in FIG. 2.

For example, in case a discrete signal S1 whose amplitude is large is received from the start, the related art digital filter 20 shown in FIG. 2 outputs a post-FIR-filter signal S21 with long transient response time as shown in FIG. 4.

Meanwhile, the digital filter 10 of the invention shown in FIG. 1 is capable of minimizing the transient response time shown in FIG. 4 thus limiting the frequency band.

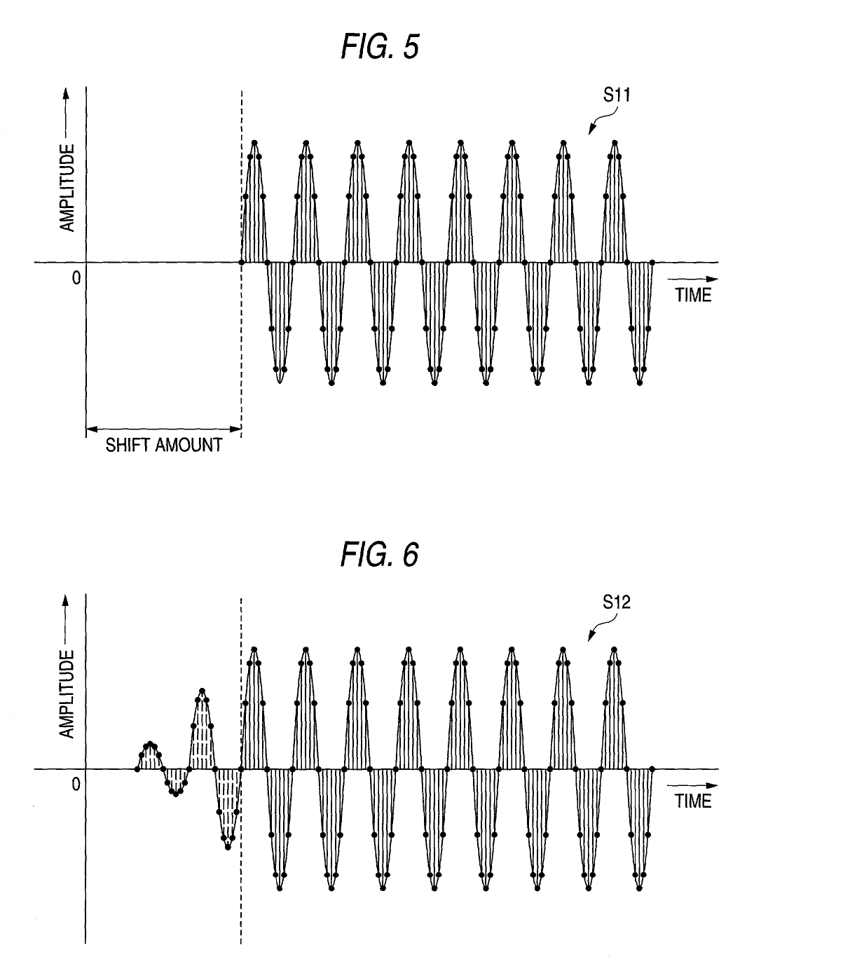

The discrete signal shift section 11 outputs a post-shift signal S11 obtained by seemingly delaying the discrete signal S1 with respect to time as shown in FIG. 5.

The shift amount is arbitrary, as long as it has no effect on the backward filter 12.

The discrete signal data at the shift portion is equivalent to the state without amplitude, so that a value of “0” is assumed.

The backward filter 12 performs filtering of the post-shift signal S11, that is, the discrete signal S1 delayed with respect to time in backward direction of time (from the new discrete signal to old discrete signal) as shown in FIG. 5 while preventing divergence caused by a feedback circuit characteristic of an IIR filter. Then the backward filter 12 outputs a post-backward-filter signal S12 having an older discrete component than the initial discrete signal.

The older discrete component than the initial discrete signal is represented by the wave section drawn with a dotted line in FIG. 6, which is discrete signal data obtained-until the feedback circuit in the backward filter 12 becomes stabilized.

The forward filter 13 performs filtering of the post-backward-filter signal S12 containing an older discrete component than the initial discrete signal in forward direction of time (from the old discrete signal to new discrete signal) and outputs a post-forward-filter signal S13 where divergence caused by a feedback circuit characteristic of an IIR filter is prevented.

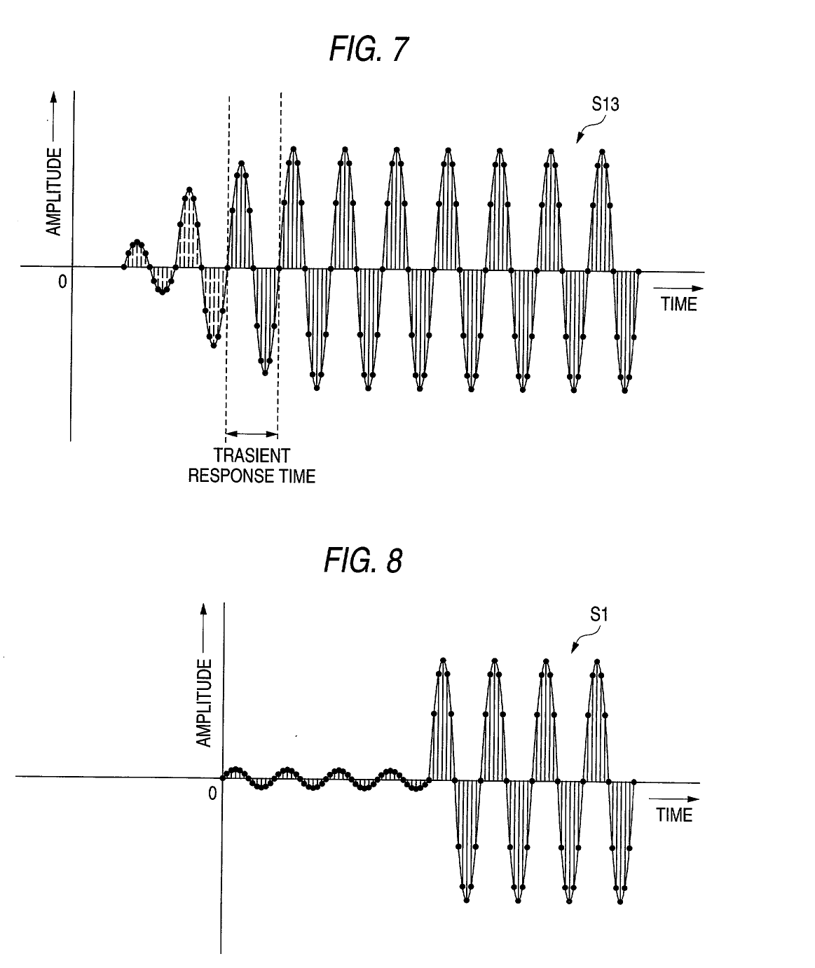

The post-forward-filter signal S13 is obtained by the forward filter 13 filtering the post-backward-filter signal S12 containing an older discrete component than the initial discrete signal, that is, the post-backward-filter signal S12 containing the wave section drawn with a dotted line in FIG. 6. Thus the transient response time of the post-forward-filter signal S13 is extremely short as shown in FIG. 7.

The number of data items of the post-forward-filter signal S13 is larger than the number of data items of the discrete signal S1 by the number of discrete signal shifted by the discrete signal shift section 11.

This discrete signal data corresponding to the shift amount should be deleted from the chronologically older discrete signal of the post-forward-filter signal S13 corresponding to the wave section drawn with a dotted line in FIG. 7, if necessary.

An example of another operation will be described.

In case a discrete signal S1 whose amplitude is larger past halfway is received, provided the discrete signal data in the section of small amplitude is infinitely close to “0” and the section of small amplitude is long enough for the feedback circuit of the backward filter 12 to be stabilized, the section of small amplitude may be treated equivalent to the discrete signal portion shifted by the discrete signal shift section 11.

In this case, it is possible to omit the discrete signal shift section 11 from the digital filter 10.

According to the first aspect of the invention, a novel digital filter with excellent transient response and having a linear phase characteristic is obtained by composing a digital filter with a backward filter 12 for inputting a discrete signal S1 and a filter coefficient S14 and outputting a post-backward-filter signal S12 and a forward filter 13 for inputting the post-backward-filter signal S12 and the filter coefficient S14 and outputting a post-forward-filter signal S13.

According to the second aspect of the invention, by using IIR digital filters as a backward filter and a forward filter, it is possible to obtain a steep attenuation characteristic of a digital filter according to the first aspect with a small number of taps. This solves the problem of that the IIR filter has a nonlinear phase characteristic.

According to the third aspect of the invention, by providing delay means (discrete signal shift section) for delaying an input discrete signal in the earlier stage of the backward filter, it is possible to suppress divergence of the IIR digital filter as well as-reduce the duration of transient response.

According to the fourth aspect of the invention, by sharing the same filter coefficient between the backward filter and the forward filter, it is possible to reduce the capacity of a table storing the filter coefficient as well as obtain a linear phase characteristic.

According to the fifth aspect of the invention, by arranging so that the input discrete signal will pass through the backward filter and the forward filter a plurality of times, it is possible to provide a more favorable frequency band limitation.

According to the sixth aspect of the invention, by arranging so that the input discrete signal will pass through the backward filter and the forward filter a plurality of times and that the number of times is identical between both filters, it is possible to obtain a linear phase characteristic.

As mentioned earlier, according to the invention, it is possible to prevent divergence of an IIR filter as well as obtain a steep attenuation characteristic and linear phase characteristic. Thus it is possible to provide a digital filter that minimizes the transient response time thus limiting the frequency band.

What is claimed is:

1. A digital filter comprising:
a backward filter for inputting a discrete signal and a filter coefficient, and outputting a post-backward-filter signal, and
a forward filter for inputting the post-backward-filter signal and the filter coefficient, and outputting a post-forward-filter signal.

2. The digital filter according to claim 1, wherein
IIR digital filters are used as said backward filter and said forward filter.

3. The digital filter according to claim 1, further comprising:
delay means for delaying an input discrete signal provided in an earlier stage of said backward filter.

4. The digital filter according to claim 1, wherein
a same filter coefficient is shared between said backward filter and said forward filter.

5. The digital filter according to claim 1, wherein an input discrete signal passes through said backward filter and said forward filter a plurality of times respectively.

6. The digital filter according to claim 5, wherein
an input discrete signal passes through said backward filter and said forward filter a plurality of times, and
the number of times is identical between said backward filter and said forward filter.
